(19) United States
(12) Patent Application Publication
(10) Pub. No.: US 2007/0028834 A1
(43) Pub. Date: Feb. 8, 2007

(54) Wafer holder for wafer prober and wafer prober equipped with same

(75) Inventors: Tomoyuki Awazu, Itami-shi (JP); Katsuhiro Itakura, Itami-shi (JP); Masuhiro Natsuhara, Itami-shi (JP); Hirohiko Nakata, Itami-shi (JP)

Correspondence Address: GLOBAL IP COUNSELORS, LLP, 1233 20TH STREET, NW, SUITE 700, WASHINGTON, DC, 20036-2680, US

(73) Assignee: Sumitomo Electric Industries, Ltd., Osaka-shi (JP)

(21) Appl. No.: 11/496,022

(22) Filed: Jul. 31, 2006

(30) Foreign Application Priority Data
Aug. 4, 2005 (JP) 2005-226205

(51) Int. Cl. C30B 25/00

(52) U.S. Cl. 117/100

(57) ABSTRACT

The present invention provides a wafer prober wafer holder that is highly rigid and increases the heat insulating effect, thereby improving positional accuracy, thermal uniformity, and chip temperature ramp-up and cooling rates, as well as a wafer prober device equipped therewith. A wafer holder of the present invention includes a chuck top that mounts a wafer, and a support member that supports the chuck top. A cavity is formed between the chuck top and the support member, and a vacuum space member is provided to the lowest part of a member that is attached to a surface of the chuck top on the side opposite the wafer mounting surface.

### TECHNICAL FIELD

The present invention relates to: a wafer holder, which is used in a wafer prober for inspecting the electrical characteristics of a wafer, that mounts a semiconductor wafer on a wafer mounting surface and presses a probe card against the wafer; a heater unit; and a wafer prober equipped with the wafer holder and the heater unit.

### BACKGROUND ART

In the conventional semiconductor inspection process, semiconductor substrates (wafers) to be processed are heat treated. Namely, a burn-in process that prevents post-shipment failures is performed by heating a wafer to a temperature higher than its normal working temperature in order to accelerate the failure of semiconductor chips that might potentially fail at a later time, and then eliminating the semiconductor chips that fail in that process. After the semiconductor circuits are formed on the semiconductor wafer and before the chips are diced, the burn-in process measures the electrical performance of each chip while heating the wafer, and then eliminates the defective chips. To improve the throughput of the burn-in process, there is a strong demand to reduce process time.

Such a burn-in process employs a chuck top that has a built-in heater for heating the wafer. The conventional chuck top is made of metal because the entire rear surface of the wafer must contact a ground electrode. When measuring the electrical characteristics of a chip, the wafer, whereon a circuit is formed, is mounted on the metal chuck top that has the built-in heater. Furthermore, an operation is performed repeatedly wherein a drive system moves a wafer holder equipped with the chuck top to a predetermined position and presses a probe, which is called a probe card and is provided with numerous current carrying electrode pins, against the wafer with a force of several dozen to several hundred kilogram-forces (kgf). Consequently, there is a problem in that the chuck top unfortunately deforms if it is thin, which causes contact failures between the wafer and the probe pins. Accordingly, a thick metal plate with a thickness of at least 15 mm must be used in order to maintain the rigidity of the chuck top and the wafer holder; however, in such a case, the heater requires a long time to ramp its temperature up and down, which is a significant impediment to improving throughput.

In addition, the electrical characteristics of a chip are measured by causing an electric current to flow through it during the burn-in process; however, the increasing output power of chips in recent years causes them to generate large amounts of heat during measurement of their electrical characteristics, and, in some cases, the heat generated by the chips themselves causes them to self destruct; consequently, there is a demand to rapidly cool the chips after the measurement is finished. In addition, there is a demand that heating during measurement be as uniform as possible. Therefore, copper (Cu), which has a high thermal conductivity of 403 W/mK, is used as a metal material.

Accordingly, Japanese Published Unexamined Patent Application No. 2001-033484 proposes a wafer prober that, instead of using a thick metal plate, resists deformation and achieves small thermal capacity by forming a thin metal layer on the surface of a ceramic substrate, which is resistant to deformation and is highly rigid, albeit thin. The abovementioned publication discloses that the chuck top has small thermal capacity and that contact failures do not occur because of its high rigidity, making it possible to ramp the temperature up and down in a short time period. Furthermore, the publication discloses that, for example, an aluminum alloy or stainless steel can be used for a support platform whereon the wafer prober can be installed. However, if the wafer prober is supported only at its outermost circumference, then the pressing of the probe card could warp the wafer prober, and therefore a design is needed that, for example, provides numerous support posts.

Nevertheless, attendant with the increasing fineness of semiconductor processes in recent years, the load per unit surface area during measurement has increased, and it is no longer possible using just the abovementioned technology to sufficiently suppress deformation during measurement, which has created a situation wherein contact failures cannot be completely prevented. At the same time, the increasing fineness of semiconductor processes has brought increased demand for higher positioning precision of the probe card and the wafer holder. When heating a wafer to a predetermined temperature of, for example, approximately 100° to 200° C., that heat is transferred to the drive system that moves the wafer holder, which creates a phenomenon wherein the metal parts of the drive system thermally expand, and positional accuracy thereby degrades.

Furthermore, the increased load during probing has led to a demand for the rigidity of the prober itself, whereon the wafer is mounted. Namely, if the prober itself deforms due to the load during probing, then problems arise in that the pins of the probe card can no longer uniformly contact the wafer, the wafer can no longer be inspected, or, in the worst case, the wafer can be damaged. Consequently, the size of the prober is unfortunately increased in order to suppress deformation of the prober, and there is a problem in that its weight increases, which adversely affects the accuracy of the drive system. Moreover, the increased size of the prober considerably lengthens the heating and cooling times of the prober, which reduces throughput.

Furthermore, to increase throughput, a cooling mechanism is often provided to accelerate the prober's temperature ramp-up/ramp-down rate. Nevertheless, the cooling mechanism is conventionally air-cooled as in, for example, Japanese Published Unexamined Patent Application No. 2001-033484, or is a cooling plate that is provided directly below the metal heater. In the case of the former, the mechanism is air-cooled, which causes the problem of a slow cooling rate. In the case of the latter, the cooling plate is made of metal, and the pressure of the probe card acts directly upon the cooling plate during probing, which causes a problem in that the cooling plate is prone to deformation.

In addition, there are cases in which the temperature at which probing is performed is lower than −40° C., and a cooling mechanism that uses a coolant is sometimes employed. In such circumstances, it is often the case that the temperature is cooled from room temperature using a coolant of a temperature that is less than −50° C., and there is a demand to cool the temperature of the prober, principally the chuck top, in a short time period in order to improve throughput. Nevertheless, the process of cooling to a temperature below the freezing point is affected by the surrounding environment, and, depending on the control of conditions, there is consequently a limit to the degree to which the cooling rate can be increased.

### DISCLOSURE OF INVENTION

The present invention was created to solve the abovementioned problems. It is an object of the present invention to provide a wafer prober wafer holder that is highly rigid and increases the heat insulating effect, thereby improving positional accuracy, thermal uniformity, and chip temperature ramp-up and cooling rates, as well as a wafer prober device equipped therewith.

A wafer holder of the present invention comprises: a chuck top that mounts a wafer; and a support member that supports the chuck top; wherein, a cavity is formed between the chuck top and the support member; and a vacuum space member is provided to the lowest part of a member that is attached to a surface of the chuck top on the side opposite the wafer mounting surface.

The member that is attached to the surface of the chuck top on the side opposite the wafer mounting surface preferably includes a cooling module.

The surface area of the vacuum space member is preferably at least 30% of the surface area of the chuck top, and its height is preferably at least 0.1 mm.

In addition, a wafer holder of the present invention comprises: a chuck top that mounts a wafer; and a support member that supports the chuck top; wherein, a cavity is formed between the chuck top and the support member; and a vacuum is created in the cavity.

A heater unit for a wafer prober comprising such a wafer holder, and a wafer prober comprising the heater unit are highly rigid and increase the heat insulating effect, thereby improving positional accuracy, thermal uniformity, and chip temperature ramp-up and cooling rates.

According to the present invention, it is possible to provide a wafer holder, which comprises a chuck top that mounts and fixes a wafer as well as a support member that supports the chuck top, wherein a cavity is formed between the chuck top and the support member, and a vacuum space member is provided to the lowest part of the member attached to the surface of the chuck top on the side opposite the wafer mounting surface, or a vacuum is created in the cavity, which enhances the heat insulating effect and therefore makes it possible to improve the heating and cooling rates of a semiconductor that has microcircuitry that demands high precision processing.

### BRIEF DESCRIPTION OF DRAWINGS

FIG. 1 shows an example of the cross sectional structure of a wafer holder of the present invention.

FIG. 2 shows an example of the cross sectional structure of a vacuum space member of the present invention.

FIG. 3 shows an example of a heater of the present invention.

FIG. 4 shows an example of the cross sectional structure of an electrode part of the wafer holder of the present invention.

FIG. 5 shows an example of the heat insulating structure of the present invention.

FIG. 6 shows another example of the heat insulating structure of the present invention.

FIG. 7 shows yet another example of the heat insulating structure of the present invention.

FIG. 8 shows an example of the cross sectional structure of the wafer holder of the present invention.

FIG. 9 shows another example of the cross sectional structure of the wafer holder of the present invention.

FIG. 10 shows yet another example of the cross sectional structure of the wafer holder of the present invention.

FIG. 11 shows yet another example of the cross sectional structure of the wafer holder of the present invention.

### BEST MODE FOR CARRYING OUT THE INVENTION

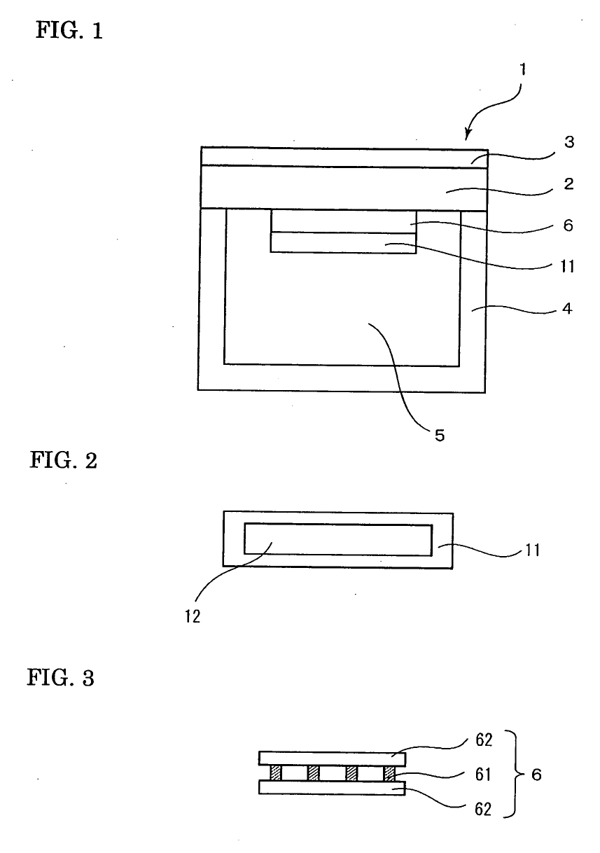

An embodiment of the present invention will now be explained, referencing FIG. 1. FIG. 1 is an example of the embodiment of the present invention. A wafer holder 1 for a wafer prober of the present invention comprises a chuck top 2, which has a chuck top conducting layer 3, and a support member 4, which supports the chuck top, wherein a cavity 5 is formed between the chuck top and the support member, and a conducting material 11, which has thermal conductivity that is lower than the chuck top, is inserted in the cavity. Furthermore, the support member is equipped with a drive system (not shown) for moving the entire wafer holder.

The presence of the cavity 5 makes it possible to enhance the heat insulating effect. Although the shape of the cavity is not particularly limited, the shape should maximally suppress the transfer of cold air or of heat, which is generated by the chuck top, to the support member. Making the support member 4 a cylinder with a bottom is preferable because the area of the contact surfaces of the chuck top and the support member can be reduced, and the cavity 5 can be easily formed. The formation of such a cavity 5 makes for an efficient heat insulating structure because the majority of space between the chuck top and the support member forms an air layer.

In the present invention, it was found that the heat insulating effect can be further enhanced and the wafer holder can be rapidly heated or cooled by inserting the vacuum space member 11 in the cavity 5, or by creating a vacuum therein. If the air layer causes convection, the heat transfer effect increases, and it may not be possible to obtain the predetermined heat insulating effect. Consequently, the vacuum space member is provided to the lowest part of a member attached to the chuck top. Alternatively, a vacuum can be created in the cavity. As a result, it is possible to suppress the impact of the surrounding heat, and the increased heat insulating effect makes it possible to achieve high heating and cooling rates.

As shown in FIG. 2, the vacuum space member 11 may be manufactured and attached as a member that is provided with a vacuum space 12, or a vacuum space may be formed in a separate member, such as the abovementioned cooling module. The material for making the vacuum space member or the separate member that forms the vacuum space may be a metal, a ceramic, or another material, as long as it is a material that can maintain a vacuum. Iron, stainless steel, copper, aluminum, and their alloys are generally used as the metal, but the present invention is not limited thereto.

The method of manufacturing the vacuum space member is not particularly specified. Generally, it is simply made with two plates by machining the surface of one plate in order to form a space therein, and then joining the other plate thereto by, for example, welding or bonding. At this time, the plates may be joined with the internal space in a vacuum state. In addition, it is also acceptable to adopt a structure wherein a pathway is formed that connects the internal space to the exterior so that it can be used to draw a vacuum therethrough.

The size of the vacuum space is preferably 30% or greater than the surface area of the chuck top. If it is less than 30%, then this will principally result in the transfer of heat of other portions, thus making it impossible to obtain a superior heat insulating effect. In addition, the height of the vacuum space is preferably 0.1 mm or greater. If it is less than 0.1 mm, then, for example, the effect of heat radiation and the contact caused by the warping of the vacuum space member will cause the heat insulating effect to be inadequate.

The chuck top preferably comprises a heater 6. This is because, although there are some cases that do not require the heating of the wafer in the semiconductor inspection process, it is often the case in recent years that the wafer must be heated to approximately 100° to 200° C. Consequently, if it is not possible to prevent the transfer of the heat from the heater, which heats the chuck top, to the support member, then heat transfers to the drive system provided to the lower part of the wafer prober support member, and differences in the thermal expansion of the drive system parts cause a degradation in mechanical accuracy as well as a marked degradation in the flatness and parallelism of the upper surface (wafer mounting surface) of the chuck top. However, the present structure is a heat insulating structure and therefore the abovementioned flatness and parallelism do not markedly degrade. Furthermore, because the present structure is a hollow structure, it is comparatively lighter than a columnar support member.

As shown in FIG. 3, the heater 6 has a simple structure, which is preferable, wherein a resistance heater 61 is interposed by insulating members 62 that are made of, for example, mica. A metal material can be used for the resistance heater. For example, it is possible to use a metal foil of, for example, nickel, stainless steel, silver, tungsten, molybdenum, chrome, or an alloy thereof. Among these metals, stainless steel and Nichrome™ are preferable. When forming stainless steel or Nichrome™ into the shape of the heater, a technique such as etching can be used to form the circuit pattern of the resistance heater with relatively good accuracy. In addition, these metals are preferable because they are inexpensive and resistant to oxidation, and therefore they can withstand usage over long time periods—even at high working temperatures. There is no particular limitation on the insulators that sandwich the heater, as long as they are heat resistant insulators. For example, mica or resins—such as silicone resin, epoxy resin, or phenolic resin—can be used. If resin is used for the insulators, then filler can be dispersed in the resin in order to enhance the thermal conductivity of the insulators. The material used for the filler is not particularly limited, as long as it does not react with the resin, and may be a substance such as, for example, silicon nitride, aluminum nitride, alumina, or silica. The heater can be fixed to the chuck top by a mechanical technique, such as using screws.

Outside of the abovementioned method of forming the heater, there is, for example, a method that forms an electrical insulation layer on the surface of the chuck top on the side opposite the wafer mounting surface by a technique such as thermal spraying or screen printing, and thereupon forms a patterned conducting layer by a technique, such as screen printing or vapor deposition.

When heating the chuck top with the heater and inspecting the wafer at, for example, 200° C., the temperature of the bottom surface of the support member is preferably less than 100° C. If the temperature exceeds 100° C., then the drive system of the wafer holder will thermally expand, which will cause contact failures. In addition, if the wafer is to be inspected at room temperature after performing inspection at 200° C., then throughput will degrade because of the time needed to cool the wafer.

The Young's modulus of the support member is preferably 200 GPa or greater. This can reduce deformation of the support member itself, which can further suppress deformation of the chuck top. In addition, the Young's modulus of the support member is more preferably 300 GPa or greater. Using a material that has a Young's modulus of 300 GPa or greater is particularly preferable because it significantly reduces deformation of the support member, which can therefore be made lighter and more compact.

The thermal conductivity of the support member is preferably less than 40 W/mK. This makes it possible to further reduce the amount of heat transferred from the chuck top through the support member to the drive system of the wafer holder, thereby effectively preventing an increase in the temperature of the drive system. In particular, the thermal conductivity of the support member is preferably less than 10 W/mK because of the demand in recent years for a high probing temperature of 150° C. In addition, the thermal conductivity is more preferably less than 5 W/mK. This is because thermal conductivity on this order significantly reduces the amount of heat transferred from the support member to the drive system.

In consideration of workability and cost, the material that has the abovementioned Young's modulus and thermal conductivity is preferably mullite, alumina, or a mullite-alumina composite. Mullite is preferable because of its low thermal conductivity and a strong heat insulating effect, while alumina is also preferable because of its high Young's modulus and high rigidity. A mullite-alumina composite is preferable overall because its thermal conductivity is lower than that of alumina, and its Young's modulus is higher than that of mullite.

The wall thickness of a tubular portion of the support member, which is cylindrical with a bottom, is preferably less than 20 mm. It is unpreferable for the wall thickness to exceed 20 mm because this will increase the amount of heat transferred from the chuck top through the support member to the drive system of the wafer holder. In addition, it is unpreferable for the wall thickness to be less than 1 mm because this causes the deformation or breakage of the support member itself due to the load of the probe card. The thickness is more preferably in the range of 10 to 15 mm. Furthermore, the wall thickness of the portion of the cylindrical part that contacts the chuck top is preferably 2 to 5 mm. A thickness on this order is preferable because it provides a good balance between the strength and the heat insulating property of the support member.

In addition, the height of the tubular portion of the support member is preferably 10 mm or greater. It is unpreferable for the height to be less than 10 mm because this will increase the amount of heat transferred from the chuck top through the support member to the drive system of the wafer holder.

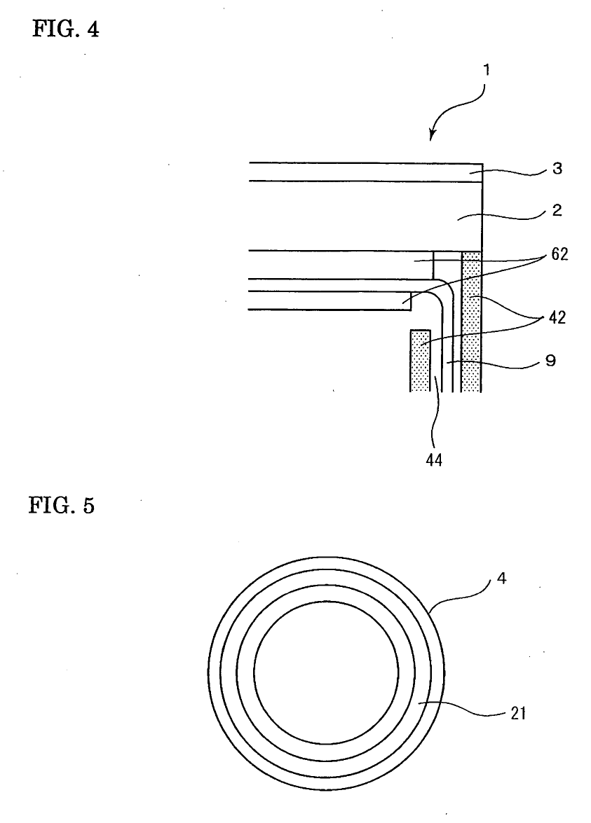

FIG. 4 shows an enlarged view of the portion where the chuck top and the tubular portion contact one another; a through hole 44 is formed in the tubular portion 42 of the support member 4 for inserting an electrode wire 9 or an electrode wire of an electromagnetic shield therethrough in order to supply electric power to the heater, which is preferable because it simplifies the routing of the electrode wire. In this case, the through hole is formed at a position near the inner circumferential surface of the tubular portion, which is preferable because it minimizes any reduction in the strength of the tubular portion. Note that the electrode wire and the through hole are omitted in drawings other than FIG. 4.

The thickness of the bottom part of the support member is preferably 10 mm or greater. It is unpreferable for the thickness of the bottom part of the support member to be less than 10 mm because this will cause deformation or breakage of the support member itself due to the load of the probe card. The thickness is preferably 10 to 35 mm. This is because if the thickness is less than 10 mm, then the heat of the chuck top will easily transfer to the bottom part of the support member, which is unpreferable because the resulting thermal expansion of the support member will cause it to warp, thereby degrading the flatness and parallelism of the chuck top. It is ideal for the thickness of the bottom part to be less than 35 mm, because this enables the support member to be made more compact. In addition, it makes it possible to separate the cylindrical part and the bottom part of the support member. In this case, the separated cylindrical part and bottom part have a mutual interface, which is preferable because it forms a thermally resistive layer that temporarily blocks the transfer of heat from the chuck top to the support member, and the temperature of the bottom part is consequently not prone to rising.

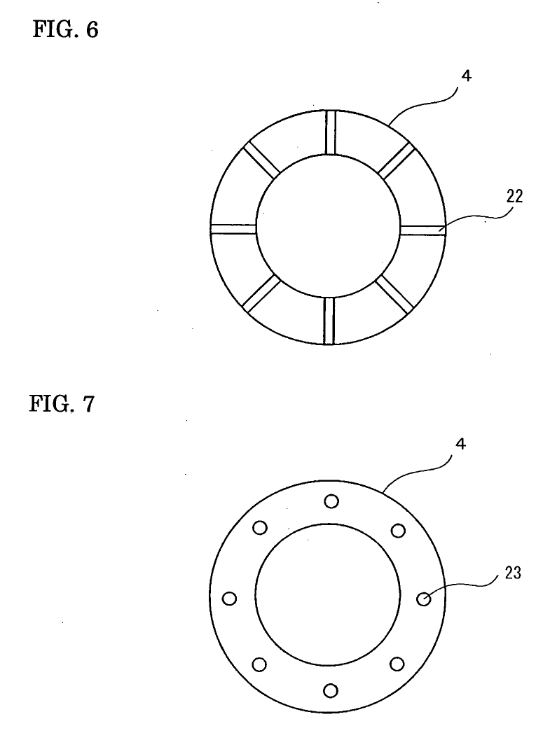

The support surface of the support member that supports the chuck top preferably has a heat insulating structure. The heat insulating structure can be created by forming notched grooves in the support member in order to reduce the area of the surfaces where the chuck top and the support member contact one another. It is also possible to form the heat insulating structure by forming the notched grooves in the chuck top. In this case, the Young's modulus of the chuck top must be 250 GPa or greater. Namely, if the pressure of the probe card is applied to the chuck top in the case where notches are present and a material with a low Young's modulus is used, then the amount of deformation of that material inevitably increases; further, if the amount of deformation increases, it may lead to, for example, breakage of the wafer or the chuck top itself. However, it is preferable for notches to be formed in the support member because such problems do not occur. The shape of the notches is not particularly limited, and may be obtained by, for example, forming: concentric grooves 21 as shown in FIG. 5; radial grooves 22 as shown in FIG. 6; or numerous projections. In any case, the notches must be symmetrically shaped. If the notches are not shaped symmetrically, then it will no longer be possible to evenly distribute the pressure applied to the chuck top, which is unpreferable because it can cause, for example, deformation or breakage of the chuck top.

In addition, the heat insulating structure is preferably formed by installing a plurality of pillar members 23 between the chuck top and the support member, as shown in FIG. 7. Eight or more pillar members 23 are preferably disposed so that they are distributed equally spaced apart between concentric circles or in a similar arrangement. In particular, because the size of wafers has increased from 8 to 12 inches in recent years, a quantity of fewer than eight pillar members will increase the distance between them, which is unpreferable because bending will occur between the pillar members when the pins of the probe card press against the wafer mounted on the chuck top. In addition, two interfaces can be formed, i.e., the interface between the chuck top and the pillar members and the interface between the pillar members and the support member; since each interface forms a thermally resistive layer, this arrangement provides double the thermally resistive layers for the case wherein the areas of the contact surfaces of the chuck top and the support member are the same, consequently making it possible to more effectively insulate the heat generated by the chuck top than the case wherein the chuck top and the support member are integrated. The shape of the pillar members is not particularly limited, and the pillar members may be columnar, triangular prisms, quadrangular prisms, pipe shaped, or any polygonal shape. Regardless of the shape, it is possible to block the transfer of heat from the chuck top to the support member by the insertion of the pillar members in this manner.

The thermal conductivity of the material of the pillar members used in the heat insulating structure is preferably less than 30 W/mK. It is unpreferable for the thermal conductivity to be higher than 30 W/mK because this reduces the heat insulating effect. Materials that can be used for the pillar members include Si₃N₄, mullite, a mullite-alumina composite, steatite, cordierite, stainless steel, glass (fibers), heat resistant resins (such as polyimide, epoxy, and phenolic resins), as well as a composite thereof.

The surfaces of the support member and the chuck top where they contact one another each preferably have a surface roughness Ra of 0.1 μm or greater. Making the surface roughness Ra 0.1 μm or greater increases the thermal resistance of the contact surfaces of the support member and the chuck top, and it is consequently possible to reduce the amount of heat transferred to the drive system of the wafer holder. There is no particular upper limit to the surface roughness. Preferable techniques to make the surface roughness Ra 0.1 μm or greater include processing the surfaces by, for example, polishing or sandblasting.

In addition to the contact surfaces of the support member and the chuck top, if the contact surfaces of the bottom surface of the support member and the drive system, the contact surfaces of the bottom part of the support member and the cylindrical portion or the pillar members (in the case wherein the bottom part of the support member is separated from the cylindrical portion or the pillar members), as well as the contact surfaces of the cylindrical portion and the plurality of pillar members (in the case wherein the cylindrical portion and a plurality of pillar members are used in combination) are likewise processed so that they have a surface roughness Ra of 0.1 μm or greater, then the thermal resistance increases, which is preferable because it can reduce the amount of heat transferred to the drive system of the wafer holder. The reduction in the amount of heat transferred to the drive system due to the increase in the thermal resistance leads to a reduction in the amount of electric power supplied to the heater.

The perpendicularity of the outer circumferential part of the cylindrical portion of the support member with respect to the surface of the support member that contacts the chuck top, and the perpendicularity of the outer circumferential portion of the cylindrical portion of the support member with respect to the surfaces of the pillar members that contact the chuck top are each preferably 10 mm or less when calculated with a measurement length of 100 mm. For example, it is unpreferable for the perpendicularities to exceed 10 mm because this will cause the cylindrical portion of the support member itself to be prone to deformation when the pressure of the chuck top is applied thereto.

It is preferable that a metal layer be formed on the surface of the support member. The electric fields and the electromagnetic waves generated by the heater that heats the chuck top, the drive unit of the prober, as well as other peripheral equipment constitute noise when inspecting the wafer, and may affect the inspection; however, forming the metal layer on the support member is preferable because it can block (shield) these electromagnetic waves. The method of forming the metal layer is not particularly limited. For example, it is possible to use a brush to coat the surface of the support member with a conducting paste wherein a glass frit has been added to a metal powder, such as silver, gold, nickel, or copper, and then bake the coated surface.

The metal layer may also be formed by thermally spraying a metal, such as aluminum or nickel. In addition, it is also possible to form the metal layer on the surface of the support member by metal plating. Furthermore, it is also possible to use a combination of these techniques. Namely, a metal such as nickel may be plated after baking the conducting paste, or after thermal spraying. Of these techniques, plating is particularly preferable because of its strong ability to adhere metals and its high reliability. In addition, thermal spraying is preferable because it is possible to form the metal film at a relatively low cost.

In addition, another possible technique is to attach a tubular conductor to a side surface of the support member. The material used is not particularly limited, as long as it is a conductor. A metal foil or a metal plate made of, for example, stainless steel, nickel, or aluminum, can be tubularly formed larger than the outer diameter of the support member, and then attached to the side surface of the support member. In addition, a metal foil or a metal plate can be attached to the bottom surface portion of the support member, and then connected to the metal foil or the metal plate attached to the side surface of the support member, thereby enhancing the effect of blocking the electromagnetic waves. In addition, a metal foil or a metal plate may be attached inside the cavity 5, which is inside the support member, and then connected to the metal foil or the metal plate that is attached to the side surface and/or the bottom surface, thereby enhancing the effect of blocking the electromagnetic waves. The use of such techniques is preferable because they can block electromagnetic waves more inexpensively than the case wherein the support member is plated or coated with a conducting paste. The method of fixing the metal foil or the metal plate to the support member is not particularly limited, and it is possible, for example, to use metal screws to attach a metal foil or a metal plate to the support member. In addition, the metal foils or the metal plates of the bottom surface part and the side surface part may be fixed to the support member after integrating them beforehand.

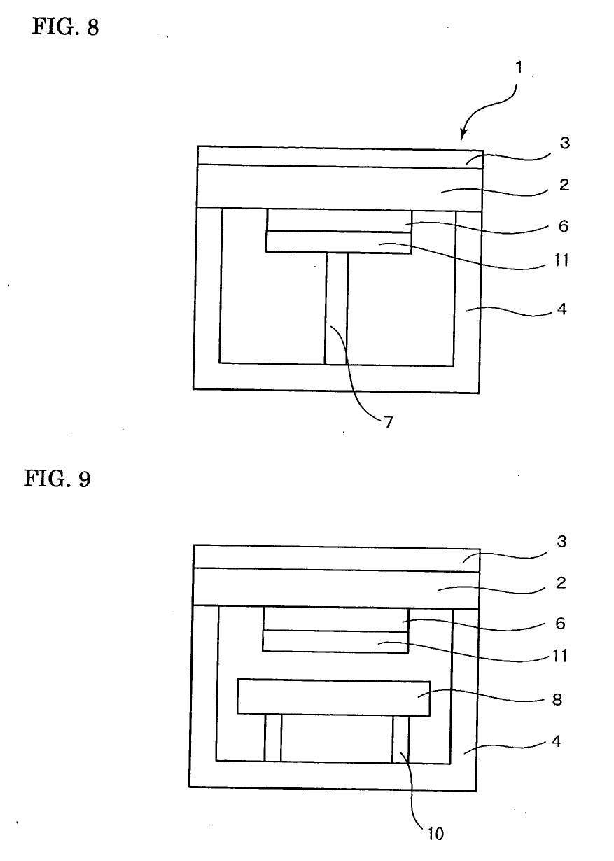

In addition, as shown in FIG. 8, it is preferable to provide a support rod 7 in the vicinity of the center part of the support member 4. This support rod can further suppress the deformation of the chuck top when the load of the probe card is applied. The material of the support rod is preferably identical to that of the tubular portion or the pillar members. It is unpreferable for the heat from the heater to thermally expand the tubular portion, the pillar members, or the support rod, in the case wherein their materials differ, because the differences in the coefficients of thermal expansion create height differences among the tubular portion, the pillar members, and the support rod. The cross sectional area of the support rod is preferably 0.1 cm² or greater. If the cross sectional area is less than 0.1 cm², then the support effect of the support rod will be insufficient, and it will tend to deform. In addition, the cross sectional area is preferably less than 100 cm². It is unpreferable for the cross sectional area to be greater than 100 cm² because this will increase the amount of heat transferred to the drive system. In addition, the shape of the support rod is not particularly limited, and the support rod may be, for example, columnar, a triangular prism, a quadrangular prism, or pipe shaped. Methods that can be cited for fixing the support rod to the support member include brazing with active metal, solder glass bonding, and fixing with screws; however, the use of screws is particularly preferable. This is because the use of screws makes it easy to attach and remove the support rod; furthermore, because heat treatment is not performed when fixing the support rod to the support member with screws, it is possible to suppress the deformation of the support member and the support rod caused by heat treatment.

In addition, to block electromagnetic waves, it is also preferable to form an electromagnetic shield layer between the chuck top and the heater that heats the chuck top. To form this electromagnetic shield layer, it is possible to use a technique that forms a metal layer on the surface of the abovementioned support member, e.g., by inserting a metal foil between the heater and the chuck top. The material of the metal foil used is not particularly limited, and it is possible to use, for example, stainless steel, nickel, or aluminum.

In addition, it is preferable to provide an electrical insulation layer between the electromagnetic shield layer and the chuck top. This electrical insulation layer serves to shield noise that affects the inspection of the wafer, such as electromagnetic waves and electric fields generated by, for example, the heater. Such noise has a marked impact particularly when measuring the high frequency characteristics of the wafer, but it does not have a significant impact on the measurement of regular electrical characteristics. Namely, a large share of the noise generated by the heater is blocked by the electromagnetic shield layer; however, a capacitor is formed in the electric circuit between the electromagnetic shield layer and the chuck top conducting layer, which is formed on the wafer mounting surface of the chuck top, in the case wherein the chuck top is an insulator, or between the heater and the chuck top itself in the case wherein the chuck top is a conductor, and this capacitor may have an effect that is the same as that caused by noise during the inspection of the wafer. To reduce that effect, an electrical insulation layer can be formed between the electromagnetic shield layer and the chuck top.

Furthermore, it is preferable to provide a guard electrode layer, which is interposed by electrical insulation layers, between the chuck top and the electromagnetic shield layer. By connecting the guard electrode layer to the metal layer formed on the support member, it is possible to further reduce effects of noise when measuring the high frequency characteristics of the wafer.

Namely, in the present invention, it is possible to reduce the effect of noise when measuring the high frequency characteristics of the wafer by covering the entire support member, including the heater, with a conductor. Furthermore, by connecting the guard electrode layer to the metal layer provided to the support member, it is possible to further reduce the effect of noise.

At this point, the resistance value of each electrical insulation layer is preferably 10⁷Ω or greater. If the resistance value is less than 10⁷Ω, then the effect of the heater causes a microcurrent to flow to the chuck top conducting layer, and this microcurrent constitutes noise during the probing, which is unpreferable because it affects probing. It is preferable for the resistance value of each electrical insulation layer to be 10⁷Ω or greater because this makes it possible to reduce the microcurrent to a level that does not affect probing. Because of the increasing fineness of the circuit patterns formed on wafers particularly in recent times, there is a need to reduce such noise as much as possible, and it is possible to further enhance reliability by making the resistance value of each electrical insulation layer 10¹⁰Ω or greater.

In addition, the permittivity of each electrical insulation layer is preferably less than 10. It is unpreferable for the permittivity of each electrical insulation layer to exceed 10 because this causes charges to accumulate on the electromagnetic shield layer, the guard electrode layer, and the chuck top that sandwich the electrical insulation layers, thereby generating noise. It has become particularly necessary in recent times to reduce noise as the fineness of wafer circuits continues to increase, as mentioned above, and therefore the permittivity is more preferably 4 or less, and yet more preferably 2 or less. It is preferable to reduce permittivity because this makes it possible to reduce the thickness of each electrical insulation layer, which is needed to ensure, for example, electrical insulation resistance or electrostatic capacitance, as well as to reduce the thermal resistance of each electrical insulation layer.

Furthermore, the electrostatic capacitance is preferably less than 5000 pF between the chuck top conducting layer and the guard electrode layer and between the chuck top conducting layer and the electromagnetic shield layer if the chuck top is an insulator, as well as between the chuck top itself and the guard electrode layer and between the chuck top itself and the electromagnetic shield layer if the chuck top is a conductor. It is unpreferable for electrostatic capacitance to exceed 5000 pF because this increases the effect wherein the electrical insulation layers function as capacitors, which act like noise during probing. The electrostatic capacitance is more preferably less than 1000 pF because this enables even a fine circuit to be inspected without being affected by noise.

As discussed above, it is possible to significantly reduce noise during inspection by controlling the resistance value, the permittivity, and the electrostatic capacitance of each electrical insulation layer so that it falls within the abovementioned ranges.

The thickness of each electrical insulation layer is preferably 0.2 mm or greater. Thinner electrical insulation layers are preferable in order to reduce the size of the device and to satisfactorily maintain the conduction of heat from the heater to the chuck top; however, it is unpreferable for the thickness of each layer to be less than 0.2 mm because this causes defects in the electrical insulation layers themselves, as well as durability problems. The thickness of each layer is preferably 1 mm or greater because this causes no durability problems and enables the satisfactory conductance of heat from the heater. The upper limit of the thickness is preferably less than 10 mm. If the thickness exceeds 10 mm, then the effect of blocking noise is strong, but the conductance of heat generated by the heater to the chuck top and the wafer takes time, which is unpreferable because it complicates the control of the heating temperature. Depending on the inspection conditions, the thickness is preferably less than 5 mm because this makes temperature control comparatively easy.

To achieve a satisfactory conductance of heat from the heater as mentioned above, the thermal conductivity of each electrical insulation layer is more preferably 0.5 W/mK or greater. In addition, the thermal conductivity is more preferably 1 W/mK or greater because this makes heat transfer more satisfactory.

Specific materials that can be cited for forming the electrical insulation layers include, for example, ceramics and resins, provided that it satisfies the abovementioned characteristics and has thermal resistance that is sufficient to withstand the temperature during inspection. Among these materials, a resin that can be satisfactorily used is, for example, silicone resin or a silicone resin wherein filler is dispersed; furthermore, a ceramic that can be satisfactorily used is, for example, alumina. The filler dispersed in the resin serves to raise the heat conduction of the resin, and materials that can be cited for the filler include substances such as boron nitride, aluminum nitride, alumina, and silica, provided it does not react with the resin.

In addition, the forming area of the present electrical insulation layers is preferably greater than or equal to the forming area of the electromagnetic shield layer, the guard electrode, and the heater. It is unpreferable for the forming area to be small because this may cause noise to penetrate through portions that are not covered by the electrical insulation layers.

The following describes an actual example of the abovementioned electrical insulation layers. First, a silicone resin, wherein boron nitride is dispersed, is used as the material. The thermal conductivity of this material is approximately 5 W/mK and its permittivity is 2. If boron nitride dispersed silicone resin is interposed as an electrical insulation layer between the electromagnetic shield layer and the chuck top, then it can be formed with a diameter of, for example, 300 mm in the case wherein the chuck top supports 12 inch wafers. At this time, if the thickness of the electrical insulation layer is 0.25 mm, then the electrostatic capacitance can be set to 5000 pF. Furthermore, if the thickness is 1.25 mm or greater, then the electrostatic capacitance can be set to 1000 pF. The volume resistivity of this material is 9×10¹⁵ Ω·cm, and the resistance value can consequently be set to 1×10¹²Ω or greater if the diameter is 300 mm and the thickness is 0.8 mm or greater. Accordingly, if the thickness is 1.25 mm or greater, then an electrical insulation layer can be obtained that has a sufficiently low electrostatic capacitance and a sufficiently high resistance value.

It is unpreferable for the warping of the chuck top to be 30 μm or greater because this causes the pins on only one side of the probe card to contact the wafer during inspection, which generates contact failures. In addition, it is unpreferable for the parallelism between the surface of the chuck top conducting layer and the bottom part rear surface of the support member to be 30 μm or greater because this similarly generates contact failures. The abovementioned warping and parallelism are preferably less than 30 μm not just at room temperature, but also across the range of temperatures at which inspections are generally performed, i.e., −70° C. to 200° C.

The chuck top conducting layer formed on the wafer mounting surface of the chuck top not only serves as a ground electrode, but also as a block for electromagnetic noise from the heater, and as protection for the chuck top against, for example, corrosive gases, acids, alkaline solutions, organic solvents, and water.

Methods that can be cited for forming the chuck top conducting layer include coating with a conducting paste by screen printing and then baking such, vapor depositing or sputtering, as well as thermal spraying or plating. Among these methods, the thermal spraying method and the plating method are particularly preferable. Because these methods of forming the conducting layer do not include heat treatment, the chuck top is not warped by heat treatment, and the conducting layer can be formed inexpensively.

A particularly preferable method of forming the chuck top conducting layer is to form a thermally sprayed film on the chuck top and then to form a plated film thereupon. During thermal spraying, the thermally sprayed material (such as aluminum or nickel) forms, for example, some oxides, nitrides, or oxynitrides, and these compounds react with the surface of the chuck top, which makes it possible to strongly and solidly adhere the thermally sprayed material to the surface of the chuck top. However, the conductivity of the film is low because the thermally sprayed film contains the above compounds. In contrast, because plating can form a metal film that is substantially pure, it forms a conducting layer that has superior electrical conductivity; however, the strength of the adhesion with the surface of the chuck top is not as great as that of the thermally sprayed film. In addition, both the thermally sprayed film and the plated film have satisfactory adhesion strength because the principle component of each one is metal. Accordingly, if a thermally sprayed film is formed as a substrate, and a plated film is then formed thereupon, then a chuck top conducting layer can be formed that has both high adhesion strength and high conductivity.

The surface roughness Ra of the chuck top conducting layer is preferably less than 0.5 μm. If the surface roughness exceeds 0.5 μm, then, when inspecting devices that generate large amounts of heat, the heat generated by the device itself cannot be dissipated from the chuck top, which may unfortunately cause the thermal destruction of the device. The surface roughness Ra is more preferably less than 0.02 μm because this enables the efficient dissipation of the heat.

When heating the heater of the chuck top and probing at a temperature of, for example, 200° C., the temperature of the lower surface of the support member is preferably less than 100° C. If the temperature exceeds 100° C., then the drive system of the prober provided to the lower part of the support member warps due to differences in thermal expansion coefficients, thereby impairing the accuracy of the drive system and causing problems, such as mispositioning during probing, warping, and one-sided contact of the probe due to warping and degradation of parallelism; consequently, the semiconductor device can no longer be accurately evaluated. In addition, if measurement is to be performed at room temperature after performing measurement at the elevated temperature of 200° C., then time is needed to lower the temperature from 200° C. to room temperature, which impairs throughput.

The thickness of the chuck top is preferably 8 mm or greater. If the thickness is less than 8 mm, then the chuck top greatly deforms when a load is applied during the inspection, which generates contact failures and, moreover, invites breakage of the wafer. The thickness of the chuck top is preferably 10 mm or greater because this further reduces the probability of contact failures.

The Young's modulus of the chuck top is preferably 250 GPa or greater. If the Young's modulus is less than 250 GPa, then the chuck top greatly deforms when a load is applied during the inspection, which generates contact failures and, moreover, invites breakage of the wafer. The Young's modulus of the chuck top is preferably 250 GPa or greater, and is more preferably 300 GPa or greater because this further reduces the probability of contact failures.

In addition, the thermal conductivity of the chuck top is preferably 15 W/mK or greater. It is unpreferable for it to be less than 15 W/mK because this degrades the uniformity of the temperature of the wafer mounted on the chuck top. If the thermal conductivity is 15 W/mK or greater, then thermal uniformity can be obtained to a degree sufficient to ensure that inspection is not hindered. The thermal conductivity is more preferably 170 W/mK or greater because this further improves the thermal uniformity of the wafer.

Materials that have a Young's modulus and thermal conductivity as described above include a variety of ceramics and metal-ceramic composite materials. The metal-ceramic composite material is preferably either a composite material of aluminum and silicon carbide (Al—SiC), or a composite material of silicon and silicon carbide (Si—SiC), which both have relatively high thermal conductivity and exhibit thermal uniformity when heating the wafer. Among these, Si—SiC is particularly preferable because it possesses a high thermal conductivity of 170 to 220 W/mK, as well as a high Young's modulus.

In addition, because these composite materials are electrically conductive, the heater can be constructed by methods such as: forming an electrical insulation layer on the surface of the chuck top on the side opposite the wafer mounting surface by techniques like thermal spraying or screen printing, and then screen printing a conducting layer thereon; or forming a conducting layer in a predetermined pattern by a technique like vapor deposition.

In addition, a heater can be constructed by forming a predetermined heater pattern by etching a metal foil made of, for example, stainless steel, nickel, silver, molybdenum, tungsten, chrome, or alloys thereof. With this method, the insulation layer between the heater and the chuck top can be formed by the same methods described above, e.g., an electrically insulated sheet can be inserted between the chuck top and the heater. This method is preferable because the electrical insulation layer can be formed much more inexpensively and easily than when using those methods described above. Resins that can be used in this method include, for example, mica sheets (which is advantageous when taking its thermal resistance into consideration), as well as epoxy resin, polyimide resin, phenol resin, and silicone resin. Among these, mica is particularly preferable. This is because mica has excellent thermal resistance and electrical insulating properties, good workability, and is also inexpensive.

Moreover, it is advantageous to use a ceramic material as the material of the chuck top because this does not require the formation of an electrical insulation layer between the chuck top and the heater. Among ceramic materials, it is preferable to use composite materials of alumina, aluminum nitride, silicon nitride, mullite, alumina, and mullite that have comparatively high Young's moduli because this reduces deformation caused by the load of the probe card. Among these, alumina is preferable from the perspective of its relatively low cost and excellent electrical insulating properties at high temperatures. In addition, oxides, such as silicon or alkaline earth metals, are generally added in order to lower the sintering temperature when sintering alumina; furthermore, if the amount of oxide added is reduced and the purity of the alumina is increased, then cost rises, but the electrical insulating property is further improved. At a purity of 99.6% or greater, excellent electrical insulating properties are obtained, and the electrical insulating property is particularly excellent if the purity is 99.9% or greater. In addition, if the purity of the alumina is increased, then the electrical insulating properties along with thermal conductivity improves, and thermal conductivity reaches 30 W/mK at a purity of 99.5%. The purity of the alumina can be appropriately selected by taking its electrical insulating properties, thermal conductivity, and cost into consideration. In addition, aluminum nitride is preferable in that it has a particularly high thermal conductivity of 170 W/mK.

In addition, it is also possible to adopt a metal as the material for the chuck top. In this case, it is possible to also use, for example, tungsten, molybdenum, or alloys thereof, each of which has a particularly high Young's modulus. Specific alloys that can be cited include tungsten-copper alloys and molybdenum-copper alloys. These alloys can be manufactured by impregnating, for example, tungsten or molybdenum with copper. As these metals are conductors like the abovementioned ceramic-metal composites, they can be used for the chuck top by forming the chuck top conducting layer and the heater using the methods described above without modification.

When a load of 3.1 MPa is applied to the chuck top, the amount of flexure thereof is preferably less than 30 μm. The pressure exerted by the probe card's numerous pins (for inspecting the wafer) pressing the wafer against the chuck top also impacts the chuck top, and bends it by no small measure. If the amount of flexure at this time exceeds 30 μm, then the pins of the probe card cannot uniformly press against the wafer, which is unpreferable in that the wafer can no longer be inspected. The amount of flexure when this pressure is applied is more preferably less than 10 μm.

In the present invention, a cooling module 8 may be provided in the cavity inside the support member 4, as shown in FIG. 9. The vacuum space member 11 is disposed so that it suppresses the transfer of heat between the cooling module and the cavity 5. A vacuum space is formed inside the cooling module, but it is also possible to make the vacuum space member and the cooling module integral. If the need arises to cool the chuck top, then the cooling module can rapidly cool the chuck top by robbing its heat, which is preferable because the chuck top can be rapidly cooled, thereby improving throughput.

Aluminum, copper, or alloys thereof are preferable as materials for forming the cooling module because their thermal conductivities are high and they can rapidly rob the heat of the chuck top. In addition, stainless steel, magnesium alloys, nickel, and other metal materials can be used. To impart oxidation resistance to the cooling module, a metal film that is resistant to oxidation, such a nickel, gold, or silver, can be formed using techniques such as plating and thermal spraying.

Ceramic materials can also be used as the material for forming the cooling module. Among ceramic materials, aluminum nitride, silicon carbide, and the like are preferable because their thermal conductivities are high and they can rapidly rob the heat of the chuck top. In addition, silicon nitride, aluminum oxynitride, and the like are preferable because of their high mechanical strength and excellent durability. Oxide ceramics, such as alumina, cordierite, and steatite, are preferable because they are relatively inexpensive. As described above, the material for the cooling module should be appropriately selected by taking, for example, application and cost into consideration. Among these materials, nickel plated aluminum, nickel plated copper, and the like are particularly preferable because they have excellent oxidation resistance, high thermal conductivities, and are relatively inexpensive.

A coolant may also flow inside the cooling module. The flow of the coolant quickly removes the heat, which transferred from the chuck top to the cooling module, from the cooling module, which is preferable because it makes it possible to raise the chuck top cooling rate. The coolant can be selected from among liquids, such as water, Fluorinert®, and Galden®, or gases, such as nitrogen, air, and helium; however, if the coolant is to be used only at temperatures greater than 0° C., then water is preferable when taking its high specific heat and low cost into consideration; furthermore, if the coolant is to be cooled to a temperature below the freezing point, then Galden® is preferable when taking its specific heat into consideration.

An example of a method for forming a passageway through which the coolant flows is to prepare two plates, and to then form the passageway in one of the plates by, for example, machining it. To improve corrosion resistance and oxidation resistance, the entire surfaces of both plates are nickel plated, and are subsequently joined together by a means such as using screws or welding. At this time, an O-ring, for example, may be inserted around the passageway so that the coolant does not leak.

In addition, as another method for forming a passageway, it is possible to attach a pipe, wherethrough the coolant flows, to a cooling plate. In this case, to increase the area of the contact surfaces of the cooling plate and the pipe, a groove, which has a cross sectional shape that is substantially the same as the pipe, is fabricated in the cooling plate, the pipe is installed in this groove, a flat surface shape is formed in part of the cross section of the pipe, and the pipe is fixed to the cooling plate by this flat surface. Methods of fixing the pipe to the cooling plate include screwing the pipe to the cooling plate with, for example, a metal band, as well as welding or brazing. If a deformable substance, such as resin, is interposed between the cooling plate and the pipe, then they can be tightly sealed to one another, thereby improving cooling efficiency.

If the cooling module can be spaced apart from the chuck top when heating the latter, then the temperature can be efficiently ramped up, and it is therefore preferable that the cooling module be movable. An example of a technique to make the cooling module movable is to use a raising and lowering means 10, such as an air cylinder. The load of the probe card is not applied to the cooling module, and therefore the problem of, for example, deformation caused by the load does not arise.

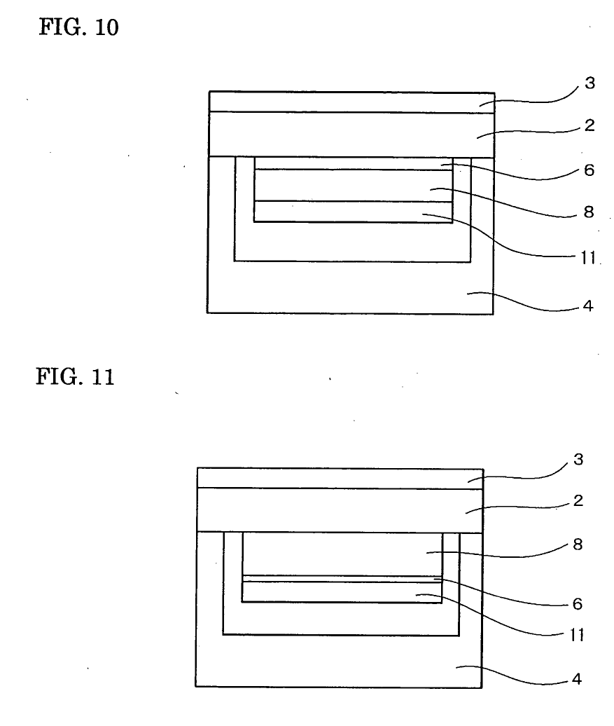

If emphasis is placed on the cooling rate of the chuck top, then the cooling module may be fixed to the chuck top. Namely, as shown in FIG. 10, the heater 6 can be installed to the chuck top 2 on the side opposite the wafer mounting surface of the chuck top 2, the cooling module 8 can be fixed to the lower surface of the heater 6, and the vacuum space member 11 can be fixed to the cooling module. In another embodiment, as shown in FIG. 11, there is a method wherein the cooling module 8 is directly installed to the chuck top 2 on the side opposite the wafer mounting surface, the heater 6 is fixed to the lower surface of the cooling module 8, and the vacuum space member 11 is fixed to the heater. At this time, a flexible material that is deformable, thermal resistant, and that has high thermal conductivity can be inserted between the cooling module 8 and the side of the chuck top 2 that is opposite the wafer mounting surface. Providing a flexible material between the chuck top and the cooling module makes it possible to alleviate problems, such as their mutual flatness and warping, to further enlarge the area of their contact surfaces, and to better achieve the originally intended cooling capacity of the cooling module, which makes it possible to raise the cooling rate.

With any of these embodiments, the fixing method is not particularly limited, and can include fixing by a mechanical technique, such as the use of screws or clamps. In addition, if fixing the chuck top, the cooling module, and the heater with screws, it is preferable to use three or more screws because this increases the tightness of the seal between the members; in addition, it is even more preferable to use six or more screws.

In addition, the cooling module may be installed in the cavity of the support member, or may be mounted on the support member, and the chuck top may then be mounted upon the cooling module. With either installation method, the chuck top and the cooling module are firmly fixed to one another, which can increase the cooling rate. If the cooling module is mounted on the support member, it increases the area of the contact surfaces of the cooling module and the chuck top, which makes it possible to cool the chuck top in a shorter period of time.

If the cooling module, which is fixed to the chuck top, is capable of cooling with a coolant, then it is preferable that the coolant does not flow through the cooling module when ramping up the temperature of the chuck top or when maintaining it at a high temperature. This is so that the heat generated by the heater is not robbed by the coolant, which makes it possible to efficiently ramp up the temperature or to maintain a high temperature. Naturally, if the coolant flows once again during cooling, the chuck top can be efficiently cooled.

Furthermore, it is also possible to provide a passageway, wherethrough the coolant flows, inside the chuck top, and to make the chuck top itself the cooling module. The cooling time in this case can be shortened much more than by fixing the cooling module 8 to the chuck top 2. Materials that can be used for the chuck top include ceramic materials and metal-ceramic composite materials, the same as above. Examples of structures include those created by forming a chuck top conducting layer on one side of a member I to serve as a wafer mounting surface, and forming the passageway on the opposite side for flowing the coolant, and then braising or solder glass bonding a member II to the surface wherein the passageway is formed; alternatively, the member I and the member II may be integrated by a technique such as the use of screws. In addition, the passageway may be formed in one side of the member II, which may then be integrated with the member I at the surface where the passageway is formed; alternatively, a passageway may be formed in both the member I and the member II, and the two may then be integrated at the surfaces where the passageways are formed. The difference in the thermal expansion coefficients between the member I and the member II is preferably on the small side, and the two are ideally made of the same material.

In addition, if the chuck top itself serves as the cooling module, then metal can be used as its material. Metals are advantageous in that they are less expensive than the abovementioned ceramics and ceramic-metal composites, and have good workability, which makes it easy to form the passageway. However, because metals easily deform under the load of the probe card, it is better to install a plate shaped member that prevents deformation of the chuck top on the side of the chuck top that is opposite the wafer mounting surface. The Young's modulus of this deformation prevention plate is preferably 250 GPa or greater, the same as the case wherein a ceramic or a metal-ceramic composite material is used as the material for the chuck top.

The deformation prevention plate may be installed inside the cavity formed in the support member, or may be inserted between the chuck top and the support member. In addition, the chuck top and the deformation prevention plate may be fixed by a mechanical technique, such as the use of screws, or by a technique such as brazing or solder glass bonding. When ramping up the temperature of the chuck top or maintaining it at a high temperature, the coolant does not flow through the cooling module and flows therethrough only during cooling, which makes it possible to efficiently ramp the temperature of the cooling module up and down; this aspect is the same as the case wherein the cooling module is fixed to the chuck top.

In addition, even if the material of the chuck top is metal, a chuck top conducting layer may be newly formed on the wafer mounting surface for reasons such as, for example, the chuck top material being prone to oxidize or deteriorate, or lacking sufficient electric conductivity. Applicable methods of forming the chuck top conducting layer include, for example, vapor deposition, sputtering, thermal spraying, or plating, the same as the abovementioned forming methods.

An electromagnetic shield layer, a guard electrode layer, or the like, the same as those mentioned above, can also be formed in the case of a structure wherein the deformation prevention plate is installed on the metal chuck top. For example, an electrically insulated heater is installed on the surface of the chuck top on the side opposite the wafer mounting surface, which is then covered with a metal layer; furthermore, a guard electrode layer is formed over an electrical insulation layer, thereby forming an electrical insulation layer between the guard electrode layer and the chuck top. Furthermore, the deformation prevention plate may be installed and the chuck top, the heater, and the deformation prevention plate may be integrally fixed to the chuck top.

If the wafer holder of the present invention is adapted to, for example, a wafer prober, a handler device, or a tester device, then a semiconductor can be inspected without contact failures, even if the semiconductor has microcircuitry.

(First Working Example)

The wafer holder 1 shown in FIG. 1 was prepared. An Si—SiC substrate with a diameter of 310 mm, a thickness of 15 mm, and a thermal conductivity of 160 W/mK was prepared as the chuck top. Concentric grooves, which are for vacuum chucking the wafer, and a through hole were formed on one surface of the substrate, and that surface was nickel plated to form a chuck top conducting layer so as to serve as the wafer mounting surface. Subsequently, the chuck top was completed by polishing the wafer mounting surface so that the overall warpage was 10 μm and the surface roughness Ra was 0.02 μm.

Next, a columnar mullite-alumina composite with a diameter of 310 mm, a thickness of 40 mm, and a thermal conductivity of 30 W/mK was prepared as the support member. After finishing the bottom surface of the support member and the surface of the support member that contacts the chuck top so that their flatnesses were 0.09 mm, the surface of the support member on the chuck top side was counterbored to a depth of 20 mm with an inner diameter of 295 mm, and the support member and the chuck top were assembled so as to form a cavity therebetween. A stainless steel foil, which was electrically insulated with mica, was attached as an electromagnetic shield layer to the chuck top, and the heater, which was interposed between mica sheets, was attached thereto. The heater was formed by etching a stainless steel foil with a predetermined pattern. The electromagnetic shield layer and the heater were disposed at a position so that they were installed in the cavity provided to the support member. In addition, the through hole for connecting the electrode that supplies electricity to the heater was formed in the support member, as shown in FIG. 4. The side surface and the bottom surface of the support member were thermally sprayed with aluminum to form a metal layer.

A stainless steel plate was used to prepare 8 types of vacuum space members, wherein vacuum spaces 12 were formed, shaped as shown in FIG. 2, in accordance with the sizes shown in the table below. Furthermore, a pipe (not shown) was attached to the vacuum space member so that a vacuum could be arbitrarily drawn in the vacuum space. In addition, the cooling module was prepared by forming a cooling passageway in one of two copper plates, and then welding the other copper plate thereto.

Next, the wafer holder was prepared by mounting the chuck top, with the heater and the electromagnetic shield layer attached, on the support member, and disposing the vacuum space member to the lower surface of the heater.

The chuck top was cooled from room temperature to −55° C. by loading the wafer holder on the wafer prober and circulating coolant (Galden®) of a temperature of −66° C. in the cooling passageway of the cooling module, and then the cooling time was measured. The results are shown in the table below.

TABLE

| | Vacuum Space Surface Area/ | Vacuum Space | Cooling |
|---|---|---|---|
| No. | Chuck Top Surface Area (%) | Height (mm) | Time (min) |
| 1 | 10 | 2 | 27.8 |
| 2 | 30 | 2 | 11.5 |
| 3 | 50 | 2 | 9.5 |
| 4 | 80 | 2 | 8.1 |
| 5 | 80 | 0.05 | 24.5 |
| 6 | 80 | 0.1 | 8.3 |
| 7 | 80 | 1.5 | 8.3 |
| 8 | 80 | 10 | 8.1 |

The cooling time for the case wherein the vacuum space member was not attached was 32.5 min; however, as can be seen from the table, it was possible to reduce the cooling time by attaching the vacuum space member and drawing a vacuum in the vacuum space. In addition, it was possible to achieve the most rapid cooling time, which was 7.7 min, in the case where a vacuum was drawn in the cavity without attaching the vacuum space member.

### INDUSTRIAL APPLICABILITY

According to the present invention, it is easy to obtain a heating device, wherein there is no concern about warping because it is highly rigid, that features high thermal conductivity of the surface upon which the object to be processed is mounted, improved thermal uniformity, and rapid cooling of chips. Consequently, if the heating device of the present invention is used in a semiconductor inspection device, such as a wafer prober, a handler device, or a tester device, then contact failures due to deformation or warping of the heating device do not occur, the entire surface of the wafer has excellent thermal uniformity, and the temperature can be ramped up and down in a short time period.

1. A wafer holder comprising:
a chuck top that mounts a wafer; and
a support member that supports said chuck top,
wherein,
a cavity is formed between said chuck top and said support member, and
a vacuum space member is provided to the lowest part of a member that is attached to a surface of said chuck top on a side opposite a wafer mounting surface of said chuck top.

2. The wafer holder as recited in claim 1, wherein
the member that is attached to the surface of said chuck top on the side opposite the wafer mounting surface includes a cooling module.

3. The wafer holder as recited in claim 1, wherein
said vacuum space member is formed such that a surface area of a vacuum space in said vacuum space member is at least 30% of the surface area of said chuck top.

4. The wafer holder as recited in claim 1, wherein
said vacuum space member is formed such that a height of a vacuum space in said vacuum space member is at least 0.1 mm.

5. The wafer holder comprising:
a chuck top that mounts a wafer; and
a support member that supports said chuck top,
wherein,
a cavity is formed between said chuck top and said support member, and
a vacuum is created in said cavity.

6. A heater unit for a wafer prober comprising the wafer holder as recited in any one of claim 1 through claim 5.

7. A wafer prober comprising the heater unit as recited in claim 6.
